(19) United States
(12) Patent Application Publication
(10) Pub. No.: US 2016/0073489 A1
(43) Pub. Date: Mar. 10, 2016

(54) MODULE

(71) Applicant: KABUSHIKI KAISHA TOSHIBA, Tokyo (JP)

(72) Inventors: Shiro HARASHIMA, Sagamihara Kanagawa (JP); Masayuki DOHI, Yokohama Kanagawa (JP); Masaki HIGA, Yokohama Kanagawa (JP); Takeshi MITSUHASHI, Yokohama Kanagawa (JP); Masaaki TAKAHASHI, Yokohama Kanagawa (JP)

(21) Appl. No.: 14/637,294

(22) Filed: Mar. 3, 2015

(30) Foreign Application Priority Data
Sep. 10, 2014 (JP) 2014-184027

(51) Int. Cl. H05K 1/02

(52) U.S. Cl. CPC H05K 1/028; H05K 1/0296; H05K 2201/055; H05K 2201/09418; H05K 2201/098

(57) ABSTRACT

A module includes a base substrate, a flexible substrate including a first portion that is disposed on the substrate and a second portion that is bent from an end of the first portion toward the first portion, and a terminal exposed at the second portion of the flexible substrate. Another module includes a substrate, a convex portion disposed on the substrate, a terminal disposed on the substrate, and a first conductive member including a first portion which is disposed on the substrate and the terminal and is connected to the terminal, and a second portion extending from the first portion and along the surface of the convex portion.

### CROSS-REFERENCE TO RELATED APPLICATION

This application is based upon and claims the benefit of priority from Japanese Patent Application No. 2014-184027, filed Sep. 10, 2014, the entire contents of which are incorporated herein by reference.

### FIELD

Exemplary embodiments described herein relate to a module.

### BACKGROUND

Semiconductor memory devices having a NAND type flash memory mounted therein are known.

### DESCRIPTION OF THE DRAWINGS

FIG. 1 is a block diagram illustrating a semiconductor memory device according to a first embodiment.

FIG. 2 is a block diagram illustrating a non-volatile semiconductor memory according to the first embodiment.

FIG. 3 is an operation concept diagram illustrating the semiconductor memory device according to the first embodiment.

FIG. 4 is a plan view illustrating a module according to Example 2-1 of a second embodiment.

FIG. 5 is a cross-sectional view taken along line V-V of FIG. 4.

FIG. 6 is a plan view illustrating a process of manufacturing the module according to Example 2-1 of the second embodiment.

FIG. 7 is a cross-sectional view taken along line VII-VII of FIG. 6.

FIG. 8 is a plan view illustrating a module according to Example 2-2 of the second embodiment.

FIG. 9 is a cross-sectional view taken along line IX-IX of FIG. 8.

FIG. 10 is a plan view illustrating a module according to Example 2-3 of the second embodiment.

FIG. 11 is a cross-sectional view taken along line XI-XI of FIG. 10.

FIG. 12 is a cross-sectional view illustrating a module according to Example 2-4 of the second embodiment.

FIG. 13 is a cross-sectional view illustrating a module according to Example 2-5 of the second embodiment.

FIG. 14 is a plan view illustrating a module according to Example 3-1 of a third embodiment.

FIG. 15 is a cross-sectional view taken along line XV-XV of FIG. 14.

FIG. 16 is a plan view illustrating a process of manufacturing the module according to Example 3-1 of the third embodiment.

FIG. 17 is a cross-sectional view taken along line XVII-XVII of FIG. 16.

FIG. 18 is a plan view illustrating a process of manufacturing the module according to Example 3-1 of the third embodiment which is subsequent to FIG. 16.

FIG. 19 is a cross-sectional view taken along line XIX-XIX of FIG. 18.

FIG. 20 is a plan view illustrating a module according to Example 3-2 of the third embodiment.

FIG. 21 is a cross-sectional view taken along line XXI-XXI of FIG. 20.

FIG. 22 is a plan view illustrating a process of manufacturing the module according to Example 3-2 of the third embodiment.

FIG. 23 is a cross-sectional view taken along line XXIII-XXIII of FIG. 22.

FIG. 24 is a plan view illustrating a process of manufacturing the module according to Example 3-2 of the third embodiment which is subsequent to FIG. 22.

FIG. 25 is a cross-sectional view taken along line XXV-XXV of FIG. 24.

FIG. 26 is a cross-sectional view illustrating a module according to Example 3-3 of the third embodiment.

FIG. 27 is a cross-sectional view illustrating a module according to Example 3-4 of the third embodiment.

FIG. 28 is a plan view illustrating a module according to a fourth embodiment.

FIG. 29 is a side view illustrating the module of FIG. 28.

FIG. 30 is a perspective view illustrating the module of FIG. 28.

FIG. 31 is a plan view illustrating a process of manufacturing the module according to the fourth embodiment.

FIG. 32 is a side view illustrating the module of FIG. 31.

FIG. 33 is a plan view illustrating a process of manufacturing the module according to the fourth embodiment which is subsequent to FIG. 31.

FIG. 34 is a side view illustrating the module of FIG. 33.

FIG. 35 is a plan view illustrating a process of manufacturing the module according to the fourth embodiment which is subsequent to FIG. 33.

FIG. 36 is a side view illustrating the module of FIG. 35.

FIG. 37 is a plan view illustrating a module according to a fifth embodiment.

FIG. 38 is a side view illustrating the module of FIG. 37.

FIG. 39 is a perspective view illustrating the module of FIG. 37.

FIG. 40 is a side view illustrating another module according to the fifth embodiment.

FIG. 41 is a plan view illustrating a process of manufacturing the module according to the fifth embodiment.

FIG. 42 is a side view illustrating the module of FIG. 41.

FIG. 43 is a plan view illustrating a process of manufacturing the module according to the fifth embodiment which is subsequent to FIG. 41.

FIG. 44 is a side view illustrating the module of FIG. 43.

FIG. 45 is a plan view illustrating a process of manufacturing the module according to the fifth embodiment which is subsequent to FIG. 43.

FIG. 46 is a side view illustrating the module of FIG. 45.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to limit the scope of the invention. As used herein, the singular forms “a,” “an” and “the” are intended to include the plurality of forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross section and perspective illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

A module which is capable of improving performance is provided.

According to an embodiment, a module includes a substrate, a flexible substrate including a first portion that is disposed on the substrate and a second portion that is bent from an end of the first portion back against the first portion, and a terminal disposed in and exposed in the second portion of the flexible substrate.

Hereinafter, embodiments will be described with reference to the accompanying drawings. Meanwhile, in the following description, elements having the same functions and configurations are denoted by reference numerals and signs common to the elements, and a repeated description will be given as necessary.

### [1] First Embodiment

A semiconductor memory device 1 of a first embodiment includes a non-volatile semiconductor memory 10, a controller 20, and a temperature sensor 30. An output terminal T3 of the temperature sensor 30 is electrically connected to a ready/busy terminal T1 of the non-volatile semiconductor memory 10 and a ready/busy terminal T2 of the controller 20. The temperature sensor 30 may stop and restart a command issue of the controller 20 in accordance with the temperature state of the non-volatile semiconductor memory 10.

### [1-1] Configuration of Semiconductor Memory Device 1

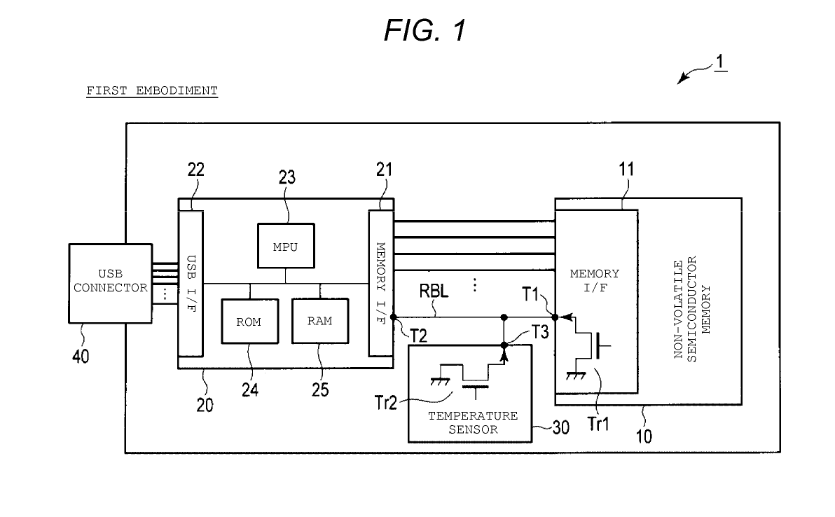

The configuration of the semiconductor memory device 1 according to the first embodiment will be described with reference to FIG. 1. Here, the semiconductor memory device 1 includes a USB (Registered Trademark) (Universal Serial Bus) memory by example, but may be, for example, an SD (Registered Trademark) card memory, a MicroSD (Registered Trademark) card memory, a CF (Compact Flash) card memory, and the like.

As shown in FIG. 1, the semiconductor memory device 1 according to the first embodiment includes the non-volatile semiconductor memory 10, the controller 20, the temperature sensor 30, and a USB connector 40.

The non-volatile semiconductor memory 10 includes a plurality of memory cells, and stores data in a non-volatile manner. The non-volatile semiconductor memory 10 includes a memory interface (I/F) circuit 11 and the like. An example of the non-volatile semiconductor memory 10 is a NAND type flash memory, and the memory interface (I/F) circuit 11 is a NAND interface circuit. The memory interface circuit 11 includes a transistor Tr1. The source of the transistor Tr1 is connected to a ground terminal. The drain of the transistor Tr1 is connected to the ready/busy terminal T1 for status checking of the non-volatile semiconductor memory 10. The transistor Tr1 is an open drain output type.

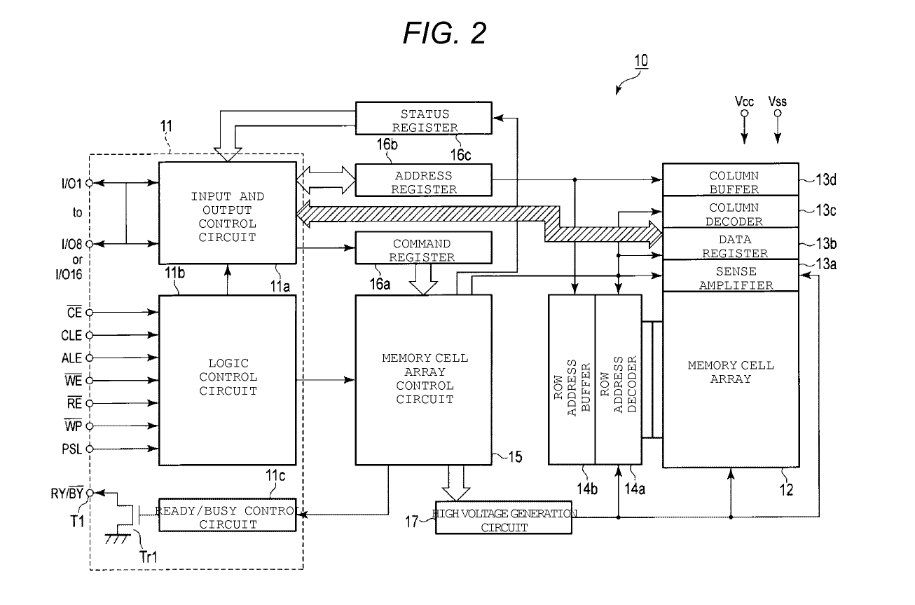

The non-volatile semiconductor memory 10 outputs a ready/busy signal for indicating the internal operating state of the non-volatile semiconductor memory 10. The non-volatile semiconductor memory 10 outputs a busy signal (RY/(/BY)=“L”) while the non-volatile semiconductor memory 10 is performing writing, reading and erasing operations of data therein, and automatically outputs a ready signal (RY/(/BY)=“H”) when these operations are completed. The configuration of the non-volatile semiconductor memory 10, and the like will be described later with reference to FIG. 2.

The controller 20 controls the reading, writing and erasing operations and the like of the non-volatile semiconductor memory 10, in response to a command from the outside of the semiconductor memory device 1. The controller 20 includes a memory interface (I/F) circuit 21, a USB interface (I/F) circuit 22, a MPU (Micro Processing Unit) 23, a ROM (Read Only Memory) 24, a RAM (Random Access Memory) 25, and the like.

The memory interface circuit 21 performs interfacing between the controller 20 and the non-volatile semiconductor memory 10. The memory interface circuit 21 includes a ready/busy terminal T2. The ready/busy terminal T2 supplies a signal (for Example, 3.3 V) of an “H” level through the controller 20.

The USB interface circuit 22 is connected to the USB connector 40, and controls the delivery of data or a command between the semiconductor memory device 1 and the outside, and the like. The number of data lines for connecting the USB interface circuit 22 and the USB connector 40 is, for example, four in the case of USB2.0, and is nine in the case of USB3.0.

The MPU 23 takes charge of the operation of the entire semiconductor memory device 1, and executes a predetermined process on the non-volatile semiconductor memory 10 in accordance with a command which is received from outside the semiconductor memory device 1. The ROM 24 stores a control program or the like which is controlled by the MPU 23. The RAM 25 is used as a work area of the MPU 23, and temporarily stores the control program or the like.

The non-volatile semiconductor memory 10 and the controller 20 are connected to each other by a plurality of data lines extending between the memory interface circuit 11 and the memory interface circuit 21. The plurality of data lines include a ready/busy line RBL. The ready/busy line RBL connects the ready/busy terminal T1 used for status checking in the memory interface circuit 11 of the non-volatile semiconductor memory 10 to the ready/busy terminal T2 used for status checking in the memory interface circuit 21 of the controller 20. The ready/busy terminal T2 receives a ready/busy signal which is output from the ready/busy terminal T1 through the ready/busy line RBL.

The temperature sensor 30 includes a transistor Tr2. The source of the transistor Tr2 is connected to the ground terminal. The drain of the transistor Tr2 is connected to the output terminal T3 of the temperature sensor 30. The transistor Tr2 is an open drain output type. The output terminal T3 of the temperature sensor 30 is connected to the ready/busy terminals T1 and T2.

The temperature sensor 30 monitors the surroundings, i.e., the vicinity of, the temperature sensor 30 (for example, of a copper pattern on a substrate which is located immediately below the temperature sensor 30), the controller 20, the non-volatile semiconductor memory 10, and the like.

In the first embodiment, an example in which the temperature sensor 30 monitors the temperature of the non-volatile semiconductor memory 10 will be described. In this case, the temperature sensor 30 is disposed, for example, on the non-volatile semiconductor memory 10 or in the vicinity of the non-volatile semiconductor memory 10. When the temperature sensor 30 monitors the controller 20, the temperature sensor 30 is disposed, for example, on the controller 20 or in the vicinity of the controller 20. When the temperature sensor 30 monitors the semiconductor memory device 1, the temperature sensor 30 may be attached, for example, separated from the semiconductor memory device 1.

The temperature sensor 30 may be mounted on the same substrate which has the non-volatile semiconductor memory 10 and the controller 20 mounted thereon. The temperature sensor 30 may be disposed adjacent to, and between, the non-volatile semiconductor memory 10 and the controller 20, as shown in FIG. 1, within the semiconductor memory device 1, or may be built into the non-volatile semiconductor memory 10 or the controller 20.

The monitoring by the temperature sensor 30 may be performed at all times, and may also be set for a predetermined period.

When the temperature of the non-volatile semiconductor memory 10 is lower than a reference value, the temperature sensor 30 turns off the transistor Tr2. As a result, the temperature sensor 30 is set to be at an “H” (high) level. On the other hand, when the temperature of the non-volatile semiconductor memory 10 is equal to or higher than the reference value, the temperature sensor 30 turned on the transistor Tr2. As a result, the temperature sensor 30 is set to be at an “L” (low) level. The reference value of the temperature of the non-volatile semiconductor memory 10 may be set in advance, for example, within the temperature sensor 30, and may also be set and changed arbitrarily from the controller 20 or the outside of the semiconductor memory device 1.

The temperature sensor 30, the controller 20 and the non-volatile semiconductor memory 10 may be directly connected to each other as shown in the drawing, and may be connected to each other through a passive component (for example, resistive element, capacitor or the like) for output adjustment.

### [1-2] Non-volatile Semiconductor Memory 10

The non-volatile semiconductor memory 10 according to the first embodiment will be described with reference to FIG. 2. As shown in FIG. 2, the non-volatile semiconductor memory 10 includes the memory interface circuit 11 having an input and output (I/O) control circuit 11a, a logic control circuit 11b and a ready/busy control circuit 11c, a memory cell array 12, a sense amplifier 13a, a data register 13b, a column decoder 13c, a column buffer 13d, a row address decoder 14a, a row address buffer 14b, a memory cell array control circuit 15, a command register 16a, an address register 16b, a status register 16c, and a high voltage generation circuit 17.

The input and output control circuit 11a transmits and receives input and output signals (I/O 1 to 8 or 16) to the controller 20.

The logic control circuit 11b receives commands from the controller 20. The commands which are received from the controller 20 are, for example, a chip enable signal/CE, a command latch enable signal CLE, an address latch enable signal ALE, a write enable signal/WE, a read enable signal/RE, a write-protect signal/WP, and a power-on select signal PSL. Here, /CE is a signal for enabling the non-volatile semiconductor memory 10. CLE is a signal for notifying the non-volatile semiconductor memory 10 that the input signal is a command. ALE is a signal for notifying the non-volatile semiconductor memory 10 that the input signal is an address signal. Here, /WE is a signal for inputting the input signal into the non-volatile semiconductor memory 10. Here, /RE is a signal for outputting the output signal from the non-volatile semiconductor memory 10. Here, /WP is a signal for protecting the non-volatile semiconductor memory 10 from writing and erasing. PSL is a signal which is used when the initial setting of the non-volatile semiconductor memory 10 is performed.

The ready/busy control circuit 11c transmits the ready/busy signal to the controller 20. The output of the ready/busy control circuit 11c is connected to the gate of the transistor Tr1. When the non-volatile semiconductor memory 10 is in a ready state, the ready/busy control circuit 11c outputs an “L” level, and the transistor Tr1 is turned off. As a result, the ready/busy signal is set to be at an “H” level. When the non-volatile semiconductor memory 10 is in a busy state, the ready/busy control circuit 11c outputs an “H” level and the transistor Tr1 is turned on. As a result, the ready/busy signal is set to be at an “L” level.

The memory cell arrays 12 each include a plurality of non-volatile memory cells associated with a word line and a bit line. The sense amplifier 13a, the data register 13b, the column decoder 13c, and the column buffer 13d sense and amplify data which is read in the bit line from the memory cell during reading of data. Write data is transferred to the memory cell during writing of data. The row address decoder 14a and the row address buffer 14b decode a block address or a page address, select a corresponding word line, and apply an appropriate voltage to a selection word line and a non-selection word line.

The memory cell array control circuit 15 controls the ready/busy control circuit 11c, the sense amplifier 13a, the data register 13b, the column decoder 13c, the row address decoder 14a, the status register 16c and the high voltage generation circuit 17. The command register 16a and the address register 16b may hold a command, an addressor the like which is received from the controller 20, and may also hold various tables. The status register 16c holds the status of the write or erase operation of data, and thereby, notifies the controller 20 of whether the operation is normally completed. The high voltage generation circuit 17 generates the voltage required for writing, reading and erasing of data, and supplies the generated voltage to the row address decoder 14a and the sense amplifier 13a. The non-volatile semiconductor memory 10 is supplied with, for example, a power supply voltage VCC and a ground voltage VSS.

### [1-3] Temperature Control of Semiconductor Memory Device 1

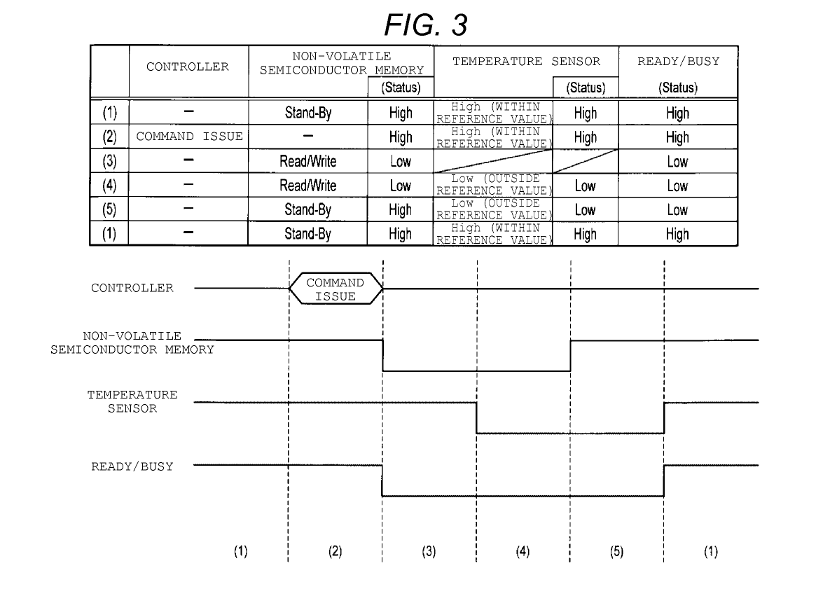

The temperature control of the semiconductor memory device 1 according to the first embodiment will be described with reference to FIG. 3. Meanwhile, the temperature sensor 30 monitors the temperature of the non-volatile semiconductor memory 10 at all times.

As shown in FIG. 3, the non-volatile semiconductor memory 10 is set at an “H” level during a standby state. In this case, when the temperature of the non-volatile semiconductor memory 10 is lower than a reference value, the temperature sensor 30 is set at an “H” level. In this case, the ready/busy signal is set at an “H” level (ready state). Thereby, the controller 20 enters a state where a command may be issued (status (1)).

When the non-volatile semiconductor memory 10 is in a ready state, the controller 20 may issue a command to the non-volatile semiconductor memory 10 (status (2)).

When the controller 20 issues a command, the non-volatile semiconductor memory 10 stores a signal, which is received from the controller 20, in the command register 16a thereof. The memory cell array control circuit 15 transmits a signal to the high voltage generation circuit 17 in accordance with the signal which is received from the controller 20. The high voltage generation circuit 17 receiving a signal applies a voltage to the memory cell array 12, the sense amplifier 13a and the row address decoder 14a, and performs reading and/or writing of data. When the reading and writing of data is performed, the memory cell array control circuit 15 transmits a signal to the ready/busy control circuit 11c. When a signal is received, the ready/busy control circuit 11c turns on the transistor Tr1. Thereby, the non-volatile semiconductor memory 10 enters a busy state (“L” level), and the ready/busy signal is set to be at an “L” level (for example, 0 V). In this case, since the non-volatile semiconductor memory 10 enters a busy state, the controller 20 enters a state where a command is not able to be issued, regardless of the status state of the temperature sensor 30 (status (3)).

When the non-volatile semiconductor memory 10 performs the reading and writing of data, the non-volatile semiconductor memory 10 generates heat, and a temperature rises. When the temperature of the non-volatile semiconductor memory 10 rises to the reference value or greater, the temperature sensor 30 is set to be at an “L” level. In this case, since the non-volatile semiconductor memory 10 and the temperature sensor 30 are set to be at an “L” level together, the ready/busy signal does not change in the state of the “L” level. In this case, the controller 20 is in a state where a command is not able to be issued (status (4)).

When the non-volatile semiconductor memory 10 terminates the read-writing operation of data, the ready/busy control circuit 11c turns off the transistor Tr1. Thereby, the non-volatile semiconductor memory 10 enters a standby state (“H” level). On the other hand, when the temperature of the non-volatile semiconductor memory 10 is higher than the reference value, the temperature sensor 30 maintains an “L” level. Thereby, the ready and busy signals are set to be at an “L” level. As a result, even when the non-volatile semiconductor memory 10 enters a standby state, from the viewpoint of the controller 20, the non-volatile semiconductor memory 10 is seen as in a busy state. Therefore, the controller 20 enters a state where a command is not able to be issued (status (5)).

When the read-writing operation of the non-volatile semiconductor memory 10 is terminated, the temperature of the non-volatile semiconductor memory 10 drops gradually. When the temperature of the non-volatile semiconductor memory 10 becomes lower than the reference value, the temperature sensor 30 is set to be at an “H” level. In this case, since the non-volatile semiconductor memory 10 and the temperature sensor 30 are set to be at an “H” level together, the ready/busy signal is set to be at an “H” level (ready state). As a result, the controller 20 enters a state where a command is able to be issued again (status (1)).

In this manner, in the semiconductor memory device 1 according to the present embodiment, when the non-volatile semiconductor memory 10 is in a high-temperature state, the ready/busy signal is set to be at an “L” level by the temperature sensor 30. Thereby, even when the non-volatile semiconductor memory 10 enters the standby state, the controller 20 will stop issuing commands for reading and/or writing.

Meanwhile, when the temperature sensor 30 is set at an “L” level due to a rise in the temperature of the non-volatile semiconductor memory 10, and the reading-writing operation of the non-volatile semiconductor memory 10 is interrupted, when the temperature sensor 30 is reset at an “H” level due to a drop in the temperature of the non-volatile semiconductor memory 10, and then the interrupted read-writing operation is performed again.

In addition, even when the non-volatile semiconductor memory 10 enters a high-temperature state due to an influence from outside of the semiconductor memory device 1 rather than the read-writing operation of the non-volatile semiconductor memory 10, the temperature sensor 30 will stop the controller 20 to stop issuing commands.

### [1-4] Effect of First Embodiment

In the semiconductor memory device 1, the generation of heat may increase due to a reduction in the size of a semiconductor element and the speedup of an operation thereof, and a temperature may rise excessively. Like a USB memory, a device having the possibility to come into direct contact with a person is not able to dissipate heat to a housing or a frame providing a heat sink. In addition, since a device in which the present non-volatile semiconductor memory 10 is mounted does not have the temperature sensor 30 mounted therein, it is not possible to control the operation of the non-volatile semiconductor memory 10 with respect to a rise in temperature.

Consequently, in the first embodiment, the semiconductor memory device 1 in which the non-volatile semiconductor memory 10 is mounted is provided with the temperature sensor 30. The output terminal T3 of the temperature sensor 30 is connected to the ready/busy terminal T1 of the non-volatile semiconductor memory 10 and the ready/busy terminal T2 of the controller 20. When the temperature of the non-volatile semiconductor memory 10 becomes equal to or higher than the reference value, the temperature sensor 30 turns on the transistor Tr2, and thus sets the ready/busy signal to be at an “L” level. Thereby, even when the non-volatile semiconductor memory 10 enters a standby state, the controller 20 sees the non-volatile semiconductor memory 10 in a busy state, and stops issuing commands.

As described above, in the temperature sensor 30, it is possible to stop issuing commands from the controller 20 in accordance with the temperature state of the non-volatile semiconductor memory 10, and to avoid a further rise in the temperature of the non-volatile semiconductor memory 10. Therefore, it is possible to control and manage the temperature of the semiconductor memory device 1 in which the non-volatile semiconductor memory 10 is mounted, and to achieve an improvement in the performance of the semiconductor memory device 1.

### [2] Second Embodiment

In a second embodiment, a molded-type module is provided with a terminal (three dimensional terminal) having a three-dimensional structure. The module according to the second embodiment may be used in the molded-type module, and may be used as, for example, a USB memory or a terminal of a USB cable. The module according to the second embodiment may be used in, for example, the USB connector 40 of FIG. 1.

### [2-1] Example 2-1

In Example 2-1, a conductive member 53 is connected to a flat terminal 52 for signal output. The conductive member 53 has a three-dimensional structure having the shape of a convex portion 51.

[2-1-1] Structure

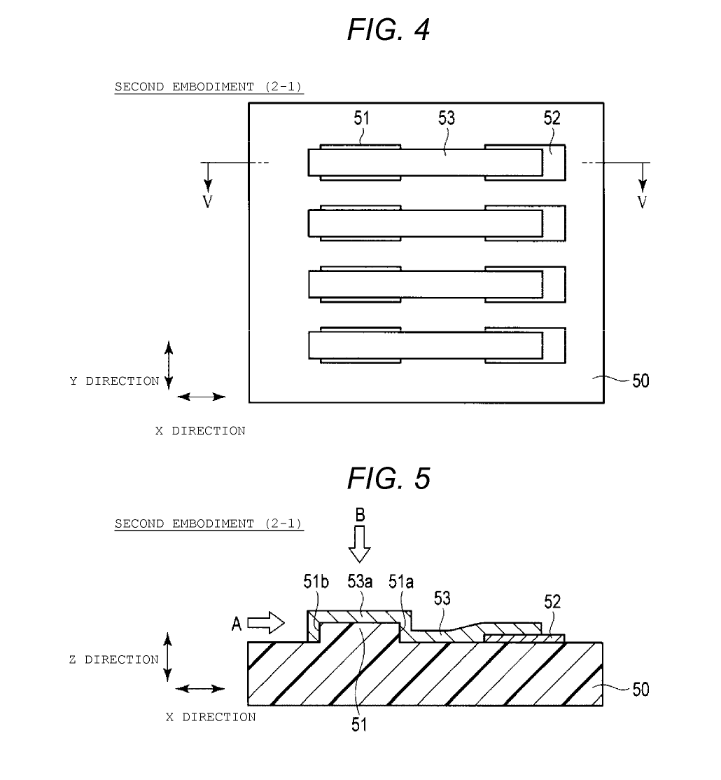

The structure of the module according to Example 2-1 will be described with reference to FIGS. 4 and 5. As shown in FIGS. 4 and 5, the module of Example 2-1 includes a substrate 50, the convex portion 51, the flat terminal 52 for signal output, and the conductive member 53.

The substrate 50 is formed of an insulating material (for example, resin). When the module according to the present embodiment is a terminal of a USB memory, or the like, the substrate 50 is formed by molding a circuit substrate in which a silicon chip is disposed integral with a molded substrate 50 body, for example.

The convex portion 51 protrudes from the upper surface of the substrate 50, and serves as a pedestal or protrusion on which the conductive member 53 is positioned. The planar shape or profile of the convex portion 51 is, for example, quadrilateral such as rectangular or square, circular, elliptical, or the like. Meanwhile, the convex portion 51 may be configured such that one or both ends thereof is angulated, i.e., it located at an angle other than parallel to the underlying surface of the substrate 50, and the other end thereof is rounded dome-shaped, or protrusion-shaped.

A plurality of convex portions 51 are disposed on the substrate 50. The convex portions 51 are disposed in a shape of individual island or mesa shaped protrusions equal in number (for example, four) of the number of flat terminals 52 and the number of conductive members 53. Meanwhile, the convex portions 51 may be disposed as one continuous protrusion extending in a Y direction (for example, the direction perpendicular to the extending direction of the conductive member 53).

Each of the convex portions 51 is formed of an insulating material, for example, the resin of the underlying substrate 50. Thus the convex portion 51 is provided integrally with the substrate 50 with the same material as that of the substrate 50. Meanwhile, the convex portion 51 may be formed of a material different from that of the substrate 50, and may be formed separately from and mounted to or over the substrate 50.

A plurality of (for example, four) flat terminals 52 are disposed on the surface of the substrate 50 on which the convex portion 51 is formed. Each of the flat terminals 52 is formed of, for example, a metal. Meanwhile, when the surface of the flat terminal 52 is exposed, a portion of or the entirety of the flat terminal 52 may be embedded within the substrate 50 so long as the end thereof overlying the convex portion 51 is exposed, i.e., not covered by insulation or other covering.

The conductive member 53 is configured such that one end thereof is connected to the flat terminal 52, and that the other end thereof extends to the convex portion 51 in an X direction along the substrate 50. The conductive member 53 covers the upper and side surfaces of the convex portion 51. Specifically, one end side (flat terminal 52 side) of the conductive member 53 is formed two-dimensionally, i.e., does not extend upwardly from the underlying substrate 50, and the other end side (convex portion 51 side) of the conductive member 53 is formed in three-dimensions, and thus extends upwardly from the underlying substrate 50 so as to have a concave shape 53a as a negative image of the shape of the convex portion 51, i.e., an upside down U-shape.

The conductive member 53 is connected to a connector (not shown) which is inserted over or past the end of the substrate 50 from the A side, in a portion facing a second lateral side 51b of the convex portion 51. However, the conductive member 53 is not required to cover the entire second lateral side 51b of the convex portion 51, and may have, for example, a structure extending from the flat terminal 52 halfway along the upper surface of the convex portion 51. The conductive member 53 is thus used to connect a connector (not shown) which is inserted from the B side to flat terminal 52.

The conductive member 53 is formed of, for example, a conductive paste or a metal foil. In the case of the conductive paste, thermoset paste, UV-curable paste or the like is used. As the material of the conductive paste, silver (Ag), palladium (Pd), copper (Cu) or the like is used. As the material of the metal foil, aluminum (Al), copper, silver or the like is used. Meanwhile, the conductive paste is preferably a material other than solder paste. The solder paste means a material formed to have a proper viscosity by adding solder powder to flux (for example, agent obtained by adding an active agent made of a halogen compound, organic acid, or haloid salt to rosin or rosin-modified resin).

A plurality of (for example, four) conductive members 53 are provided equal in number to the number of flat terminals 52.

In this manner, in Example 2-1, the conductive member 53 extends from the flat terminal 52 in the shape of the convex portion 51. Thereby, a module having a three dimensional three dimensional terminal of the concave shape 53a is formed.

[2-1-2] Manufacturing Method

A method of manufacturing the module according to Example 2-1 will be described with reference to FIGS. 4 to 7. Here, an example is given in which the substrate 50 and the convex portion 51 are formed integrally with each other.

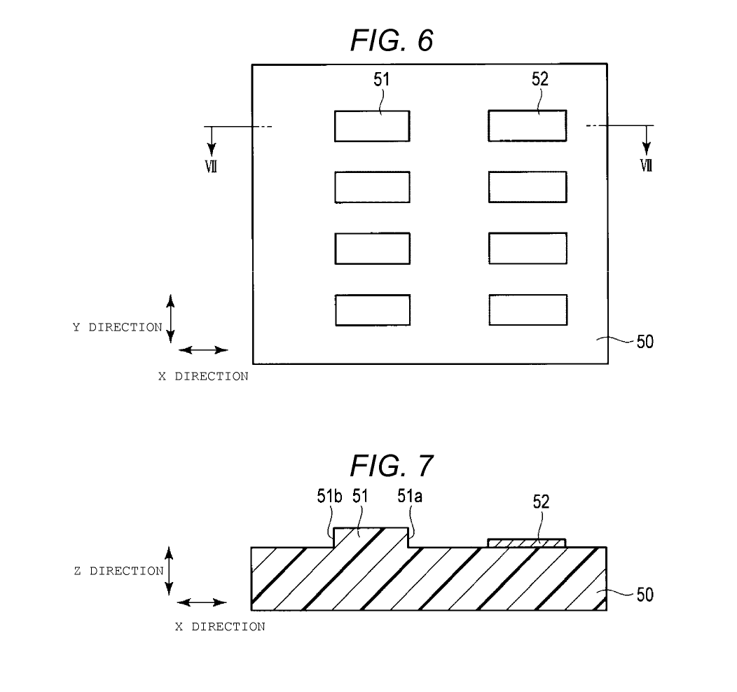

First, as shown in FIGS. 6 and 7, the substrate 50 and the convex portion 51 are formed simultaneously by molding using a sealing resin or the like. Next, the flat terminal 52 is formed on the surface of the substrate 50 on which the convex portion 51 is formed. Next, as shown in FIGS. 4 and 5, the conductive member 53 is formed from the flat terminal 52 to the convex portion 51. For example, when metal paste is used in the conductive member 53, the conductive member 53 is formed by printing. When metal foil is used in the conductive member 53, the conductive member 53 is formed by compression. As described above, a module having a three dimensional terminal which is configured with the conductive member 53 is formed.

### [2-2] Example 2-2

In Example 2-1, the conductive paste or the metal foil is used as the conductive member 53. On the other hand, in Example 2-2, a metal plate 54 is used as the conductive member. Hereinafter, only portions of the structure which are different from those in Example 2-1 will be described.

[2-2-1] Structure

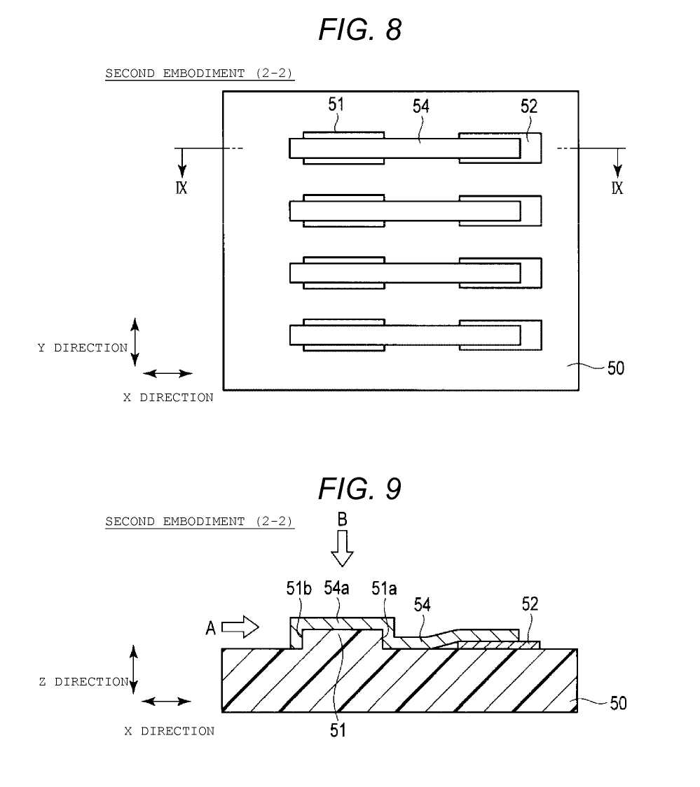

The structure of a module according to Example 2-2 will be described with reference to FIGS. 8 and 9. As shown in FIGS. 8 and 9, the module of Example 2-2 is configured such that the metal plate 54 is disposed as the conductive member which is connected to the flat terminal 52. The metal plate 54 has a concave shape 54a mimicking, as a negative image, the shape of the convex portion 51, similarly to the concave shape 53a of the conductive member 53 of Example 2-1. The metal plate 54 is formed of, for example, a material such as copper.

[2-2-2] Manufacturing Method

A method of manufacturing the module according to Example 2-2 will be described with reference to FIGS. 6 to 9. First, as shown in FIGS. 6 and 7, the substrate 50, the convex portion 51 and the flat terminal 52 are formed by the same method as that in Example 2-1. Next, as shown in FIGS. 8 and 9, the metal plate 54 is disposed on the flat terminal 52, the substrate 50 and the convex portion 51. Thereby, the concave shape 54a of the metal plate 54 having a three-dimensional structure is located so as to cover the corresponding convex portion 51. Meanwhile, the metal plate 54 having a three-dimensional structure is formed in advance so as to have the concave shape 54a following the shape of the convex portion 51. In this manner, a module having a three dimensional terminal which is configured from the metal plate 54 is formed.

### [2-3] Example 2-3

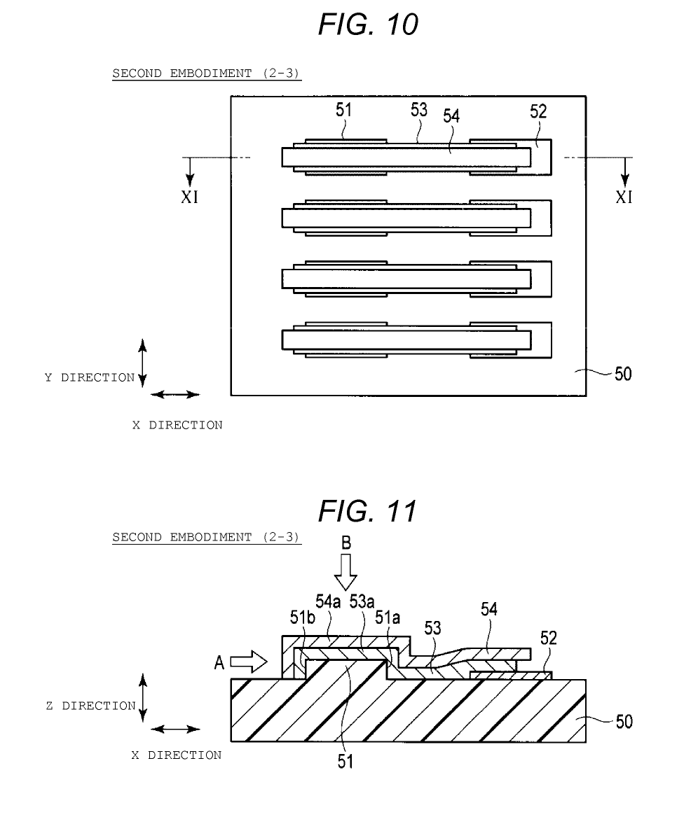

The structure of a module according to Example 2-3 will be described with reference to FIGS. 10 and 11. Hereinafter, only portions of the structures which are different from those in Example 2-1 and Example 2-2 will be described.

As shown in FIGS. 10 and 11, in the module of Example 2-3, both the conductive member (conductive paste or metal foil) 53 of Example 2-1 and the metal plate 54 of Example 2-2 are used as a three dimensional terminal which is connected to the flat terminal 52. That is, the metal plate 54 is disposed on the conductive member (conductive paste or metal foil) 53, and the metal plate 54 is connected to the flat terminal 52 through the intervening conductive member 53.

The length of the conductive member 53 extending in an X direction is smaller than the length of the metal plate 54 extending over the flat terminal 52 in the X direction, and the width of the conductive member 53 in a Y direction is larger than the width of the metal plate 54 in a Y direction (see FIG. 10), but there is no relative limitation therebetween. Additionally, the conductive member 53 need not be disposed below the entire underside of the metal plate 54. The conductive member 53 may be provided below at least a portion of the bottom of the metal plate 54 so that the electrical connection area between the metal plate 54 and the flat terminal 52 increases. For example, the conductive member 53 is not disposed between the metal plate 54 and the convex portion 51 (does not have the concave shape 53a), and the metal plate 54 may be disposed directly on the convex portion 51.

The metal plate 54 need not be disposed on the entire upper surface of the conductive member 53, and may be provided so as to cover only a portion of the conductive member 53. For example, the metal plate 54 may be disposed only above the convex portion 51, and the electrical path to the flat terminal occurs only through the conductive member 53. The metal plate 54 in that case need not have the concave shape 54a, and can be a simple planar conductive element over the portion of the conductive member 53 overlying the convex portion, where a connection occurs only in the B direction.

The conductive member 53 and the metal plate 54 may be disposed reversely. That is, the metal plate 54 may be disposed on the flat terminal 52, the substrate 50 and the convex portion 51, and the conductive member 53 may be provided on the metal plate 54.

### [2-4] Example 2-4

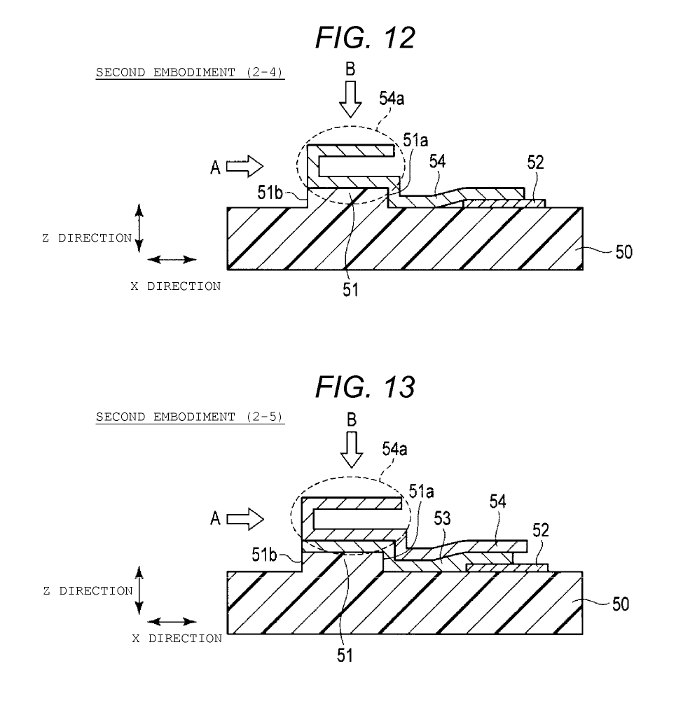

The structure of a module according to Example 2-4 will be described with reference to FIG. 12. The metal plate 54 of Example 2-4 covers a region from a first lateral side 51a of the convex portion 51 and the upper surface of the convex portion 51, but is bent to extend from the upper surface of the convex portion 51 (Z direction), and is further bent back in the direction of the flat terminal 52. In this manner, the metal plate 54 has a “C”-shape 54a which is formed three-dimensionally above the convex portion 51. Thereby, a module having a three dimensional terminal is formed.

Meanwhile, the metal plate 54 may be bent over the convex portion 51 in an arc-shape, and may have a portion which is bent back toward the upper surface of the convex portion 51 as it extends in the direction of flat terminal 52.

### [2-5] Example 2-5

The structure of a module according to Example 2-5 will be described with reference to FIG. 13. The module of Example 2-5 has a structure obtained by adding the conductive member 53 between the metal plate 54 and the substrate 50 to the module of Example 2-4. The conductive member 53 is disposed between the metal plate 54, and the flat terminal 52, the substrate 50 and the convex portion 51.

The conductive member 53 may be formed in a portion between the metal plate 54, and the substrate 50 and the convex portion 51, and the metal plate 54 may also be connected to the flat terminal 52 through the conductive member 53.

### [2-6] Effect of Second Embodiment

In the second embodiment, the conductive member 53 and the metal plate 54 which are connected to the flat terminal 52 are disposed along the convex portion 51 formed on the substrate 50 (Example 2-3). Thereby, the conductive member 53 and the metal plate 54 serve as a three dimensional terminal having the concave shapes 53a and 54a formed along the convex portion 51, as well as the C shaped portion formed on the upper surface of the convex portion 51. For this reason, since the upper surfaces of the conductive member 53 and the metal plate 54 which are located on the convex portion 51 are flattened, it is possible to secure the flatness of a signal output terminal. In addition, the conductive member 53 is formed by print or compression. Thereby, since the conductive member 53 is closely attached to the substrate 50, the convex portion 51 and the flat terminal 52, it is possible to suppress the penetration of foreign substances between the conductive member 53, and the substrate 50, the convex portion 51 and the flat terminal 52. Further, it is possible to increase a contact area between the metal plate 54 and the flat terminal 52 by providing the conductive member 53.

As described above, in the module according to the second embodiment, it is possible to improve the stability of connection between the three dimensional terminal (conductive member 53 and metal plate 54) and the flat terminal 52, and to achieve an improvement in performance.

### [3] Third Embodiment

The three dimensional terminal of the second embodiment is formed along the convex portion 51. On the other hand, a three dimensional terminal of third embodiment is not provided with the convex portion 51 or is not formed along a convex portion 51, and has a three-dimensional structure formed therein. Hereinafter, only portions of the structure which are different from those in the second embodiment will be described.

### [3-1] Example 3-1

In Example 3-1, the convex portion 51 is not provided on the substrate 50, and a three dimensional terminal is formed.

[3-1-1] Structure

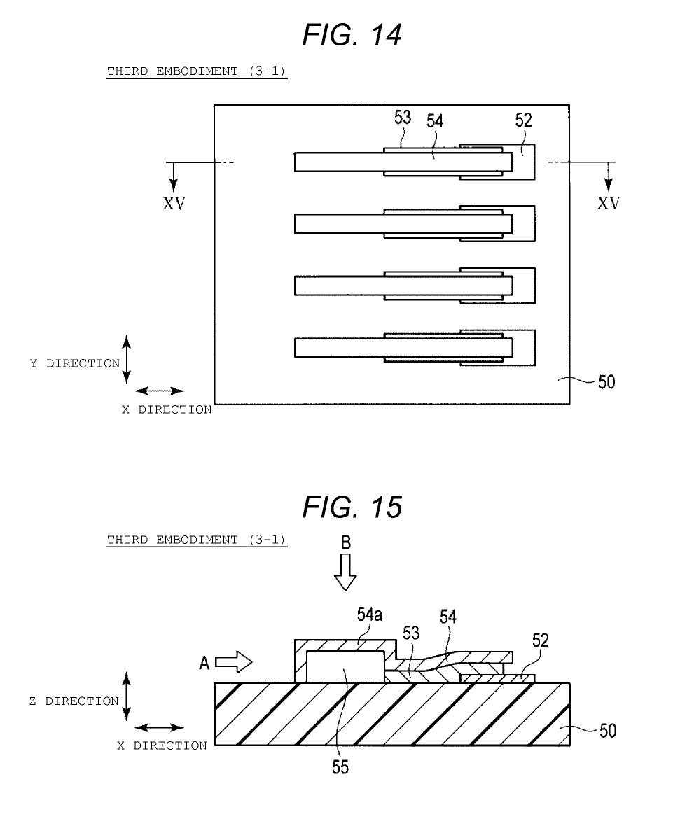

The structure of a module according to Example 3-1 will be described with reference to FIGS. 14 and 15. As shown in FIGS. 14 and 15, the module of Example 3-1 does not have the convex portion 51 provided on the substrate 50. A three-dimensional structure is formed by the concave shape 54a (up-side down U) of the metal plate 54.

Specifically, the conductive member 53 is disposed on the flat terminal 52 and the substrate 50, and is connected to the flat terminal 52. The metal plate 54 includes a first portion which is disposed on the conductive member 53 and a second portion which is bent to form the concave shape 54a. A space 55 is formed between the concave shape 54a of the metal plate 54 and the substrate 50. The distal end of the concave shape 54a of the metal plate 54 may be in contact with the substrate 50, or may be spaced from the substrate 50. The conductive member 53 is formed only below the first portion of the metal plate 54, but may extend to the lower portion of the concave shape 54a.

Meanwhile, in the module of Example 3-1, the metal plate 54 may be directly connected to the flat terminal 52 without using the conductive member 53.

[3-1-2] Manufacturing Method

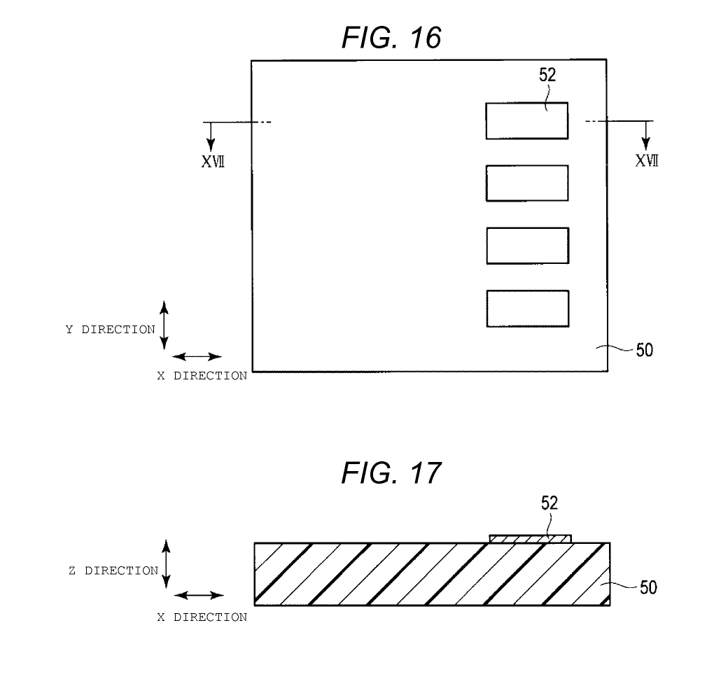

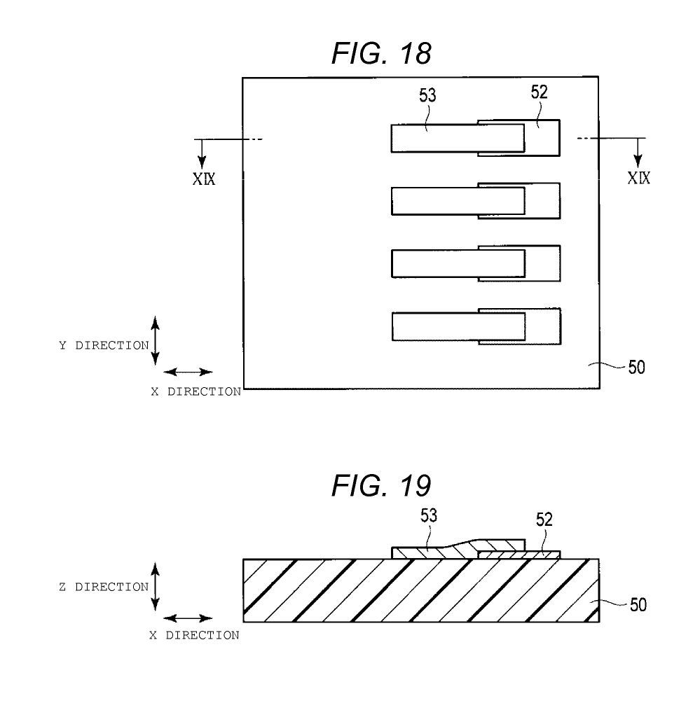

A method of manufacturing the module according to Example 3-1 will be described with reference to FIGS. 14 to 19. First, as shown in FIGS. 16 and 17, the substrate 50 is formed as a molded member by molding using a sealing resin or the like. Next, the flat terminal 52 is formed on the substrate 50. Next, as shown in FIGS. 18 and 19, the conductive member 53 is formed on the flat terminal 52 and the substrate 50. As shown in FIGS. 14 and 15, the metal plate 54 having the concave shape 54a is disposed on the conductive member 53 and the substrate 50. The metal plate 54 is connected to the flat terminal 52 through the conductive member 53. In this manner, a module having a three dimensional terminal which is configured with the conductive member 53 and the metal plate 54 is formed.

### [3-2] Example 3-2

In Example 3-2, a metal plate 54 having a concave shape 54a different from the shape of the convex portion 51 is disposed. The space 55 is provided between the second lateral side 51b of the convex portion 51 and the metal plate 54.

[3-2-1] Structure

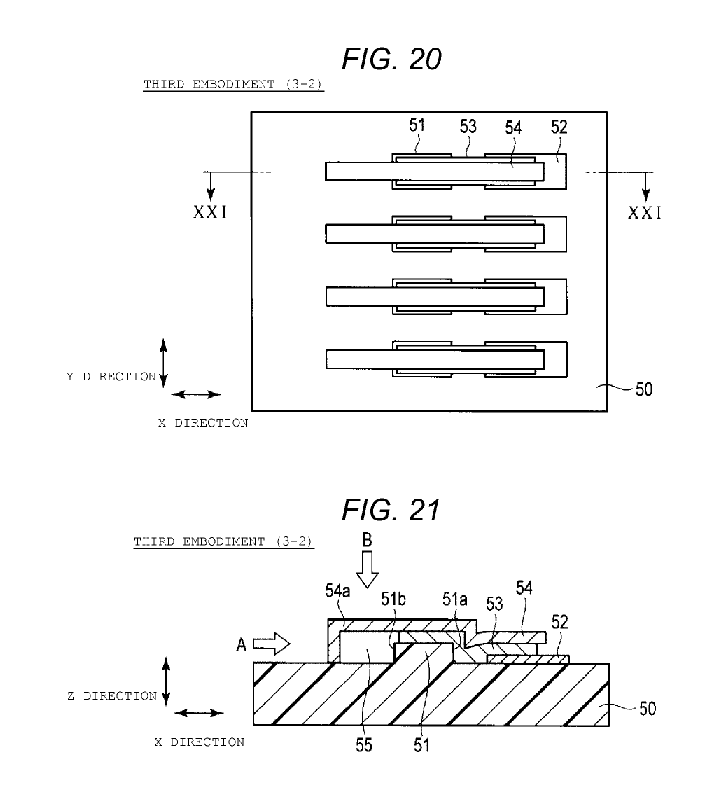

The structure of a module according to Example 3-2 will be described with reference to FIGS. 20 and 21. As shown in FIGS. 20 and 21, the module of Example 3-2 does not come into contact with, i.e., is spaced from, the second lateral side 51b of the convex portion 51 of the metal plate 54, as compared to the module of Example 2-3. Thereby, a space 55 is provided between the second lateral side 51b and the inner surface of the portion of the metal plate 54 extending downwardly in the direction of the substrate 50. In this way, the concave shape 54a of the metal plate 54 is different from that of the convex portion 51. The position of the metal plate 54 is fixed by the first lateral side 51a of the convex portion 51. Meanwhile, the end of the concave shape 54a of the metal plate 54 may be in contact with the substrate 50, or may be spaced from the substrate 50 (not shown).

One end of the conductive member 53 is connected to the corresponding flat terminal 52. The other end of the conductive member 53 is formed so as to cover a region from the first lateral side 51a of the convex portion 51 and along the upper surface of the convex portion 51 in the direction of the second lateral side 51b. The conductive member 53 is not limited to the shown shape, and may extend to the upper portion of the substrate 50 by covering, for example, a region from the flat terminal 52 to the second lateral side 51b of the convex portion 51, a region from the flat terminal 52 to a portion of the upper surface of the convex portion 51 as shown in FIG. 21, a region from the flat terminal 52 to a portion of the first lateral side 51a of the convex portion 51, or a region from the flat terminal 52 to the convex portion 51.

Meanwhile, in the module of Example 3-2, the metal plate 54 may be directly connected to the flat terminal 52 without using the conductive member 53.

[3-2-2] Manufacturing Method

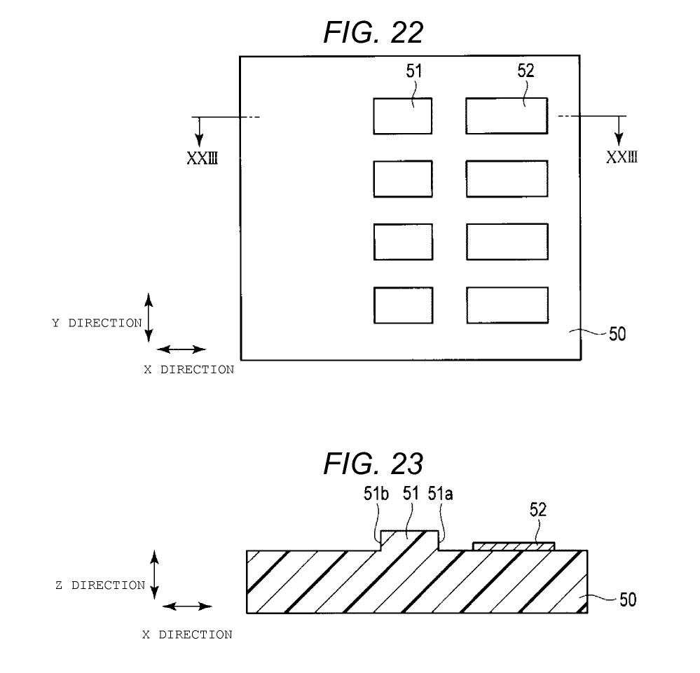

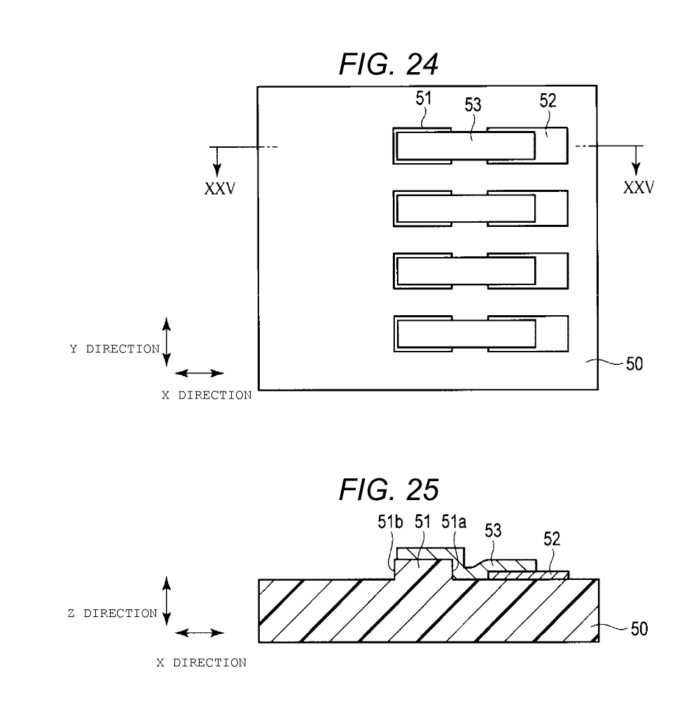

A method of manufacturing the module according to Example 3-2 will be described with reference to FIGS. 20 to 25. First, as shown in FIGS. 22 and 23, the substrate 50, the convex portion 51 and the flat terminal 52 are formed by the same method as that in Example 2-1. Next, as shown in FIGS. 24 and 25, the conductive member 53 is formed so as to cover a region from the flat terminal 52 to and along the upper surface of the convex portion 51. As shown in FIGS. 20 and 21, the metal plate 54 having the concave shape 54a is disposed on the conductive member 53 and the substrate 50. The metal plate 54 is connected to the flat terminal 52 through the conductive member 53. In this case, the metal plate 54 is positionally fixed so as to be in contact with the first lateral side 51a of the portion of the conductive member 53 in contact with convex portion 51. In this manner, a module having a three dimensional terminal which is configured with the conductive member 53 and the metal plate 54 is formed.

### [3-3] Example 3-3

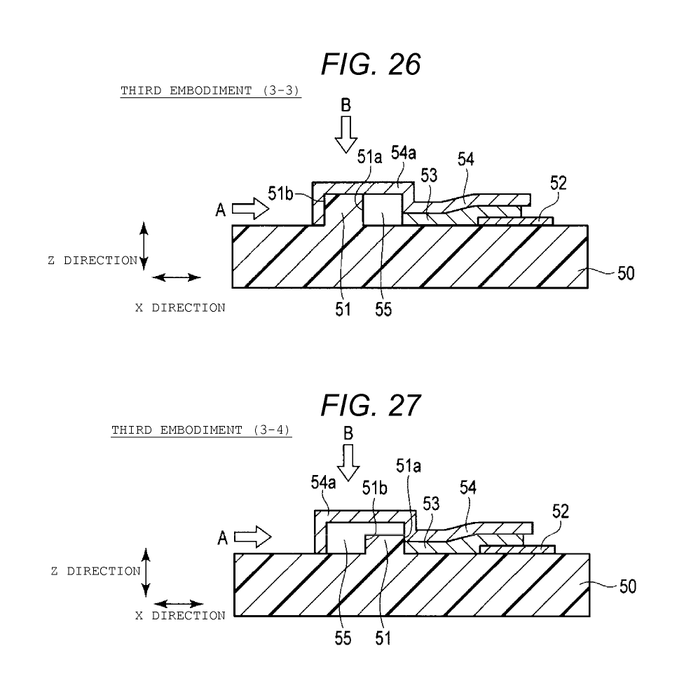

The structure of a module according to Example 3-3 will be described with reference to FIG. 26. In Example 3-2, the metal plate 54 is positionally fixed at the first lateral side 51a of the convex portion 51. On the other hand, in Example 3-3, the metal plate 54 is positionally fixed at the second lateral side 51b of the convex portion 51, and spaced from the first lateral side 51a. For this reason, the second lateral side 51b of the convex portion 51 is in contact with the metal plate 54, and the first lateral side 51a of the convex portion 51 is spaced from the metal plate 54. As a result, the space 55 is provided at the first lateral side 51a side of the convex portion 51.

Meanwhile, in the module of Example 3-3, the metal plate 54 may be directly connected to the flat terminal 52 without using the conductive member 53. In addition, in a state where the position of the metal plate 54 is fixed at the second lateral side 51b of the convex portion 51, a space may be provided on the upper surface of the convex portion 51 as in Example 3-4 described later.

### [3-4] Example 3-4

The structure of a module according to Example 3-4 will be described with reference to FIG. 27. In Example 3-4, the metal plate 54 is positionally fixed at the first lateral side 51a of the convex portion 51. In this module, space is present between the second lateral side 51b and the upper surface of the convex portion 51 and the metal plate 54, the space 55 is provided at the second lateral side 51b and the upper surface side of the convex portion.

In the module of Example 3-4, the metal plate 54 may be directly connected to the flat terminal 52 without using the conductive member 53.

### [3-5] Effect of Third Embodiment

In the third embodiment, it is possible to obtain an effect similar to that in the above-mentioned second embodiment. Further, in the third embodiment, it is possible to forma three dimensional terminal having a shape different from the shape of the convex portion 51.

### [4] Fourth Embodiment

In a fourth embodiment, in a molded-type module, a three dimensional terminal is formed by folding over a flexible substrate 62 having a flat terminal 64 thereon. The module of the fourth embodiment may be used in the overall molded-type module. For example, the module may be used in the USB connector 40 of FIG. 1. Hereinafter, an example in which the module of the fourth embodiment is applied to a male connector of USB3.0 will be described.

### [4-1] Structure

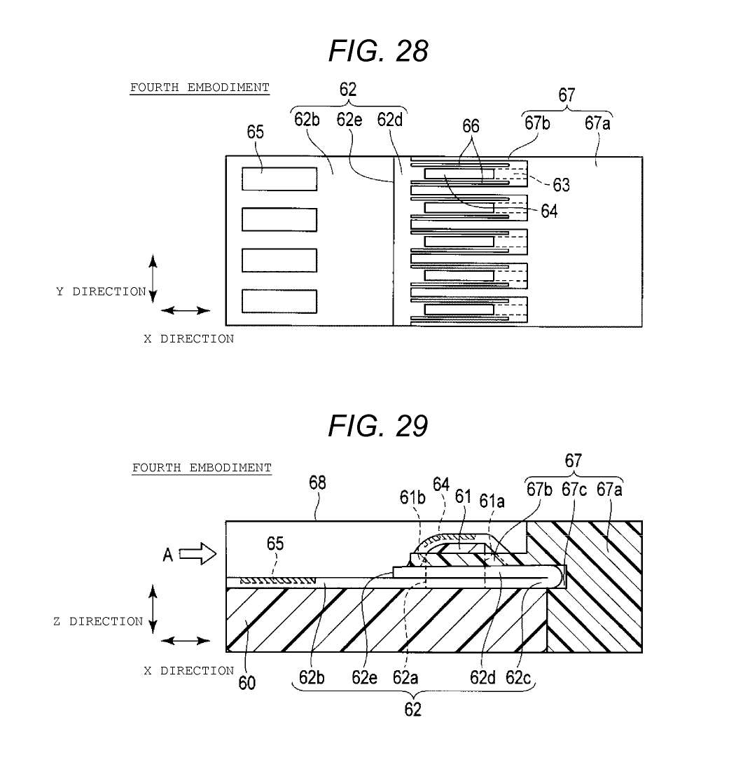

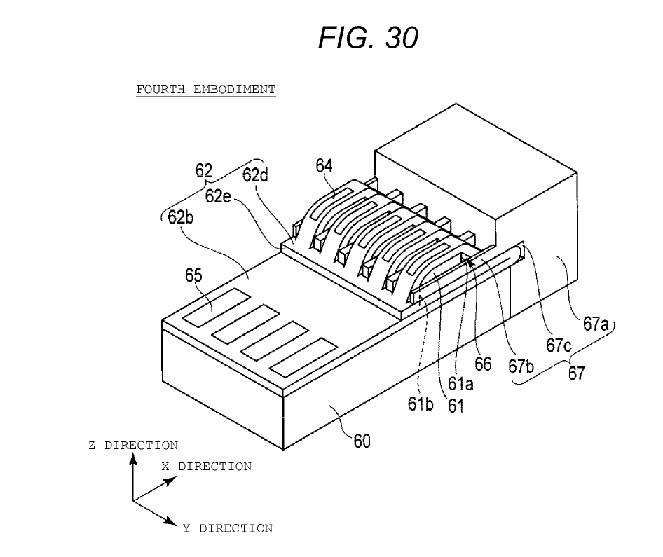

The structure of the module according to the fourth embodiment will be described with reference to FIGS. 28 to 30. Meanwhile, in FIG. 30, a housing 68 shown in FIGS. 28 and 29 is not shown.

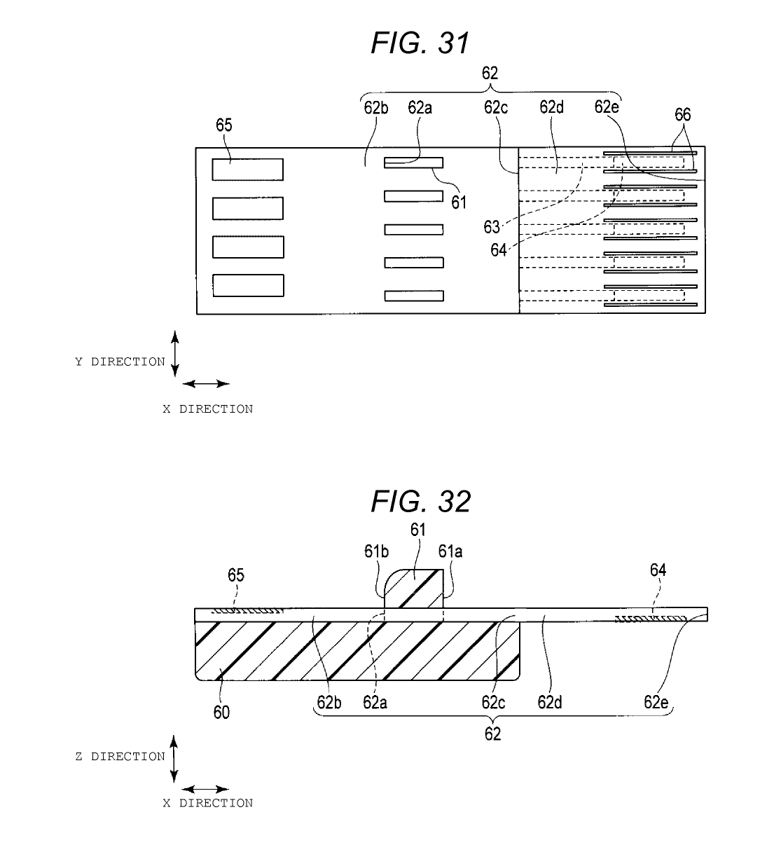

As shown in FIGS. 28 to 30, the module according to the fourth embodiment includes a substrate 60, a convex portion 61, a flexible substrate 62, an internal wiring 63 (FIG. 31) which extends from, or are exposed in, the flexible substrate 62 as flat terminals 64 and 65 for signal output, a fixing component 67 and the housing 68.

The underlying substrate 60 is formed of an insulating material (for example, resin). When the module according to the present embodiment is a terminal of a USB memory, or the like, the substrate 60 is formed by molding, for example, a circuit substrate in which a silicon chip is disposed.

The convex portion 61 protrudes from the upper surface of the substrate 60, and serves as a pedestal for receiving the flat terminal 64 on the flexible substrate 62 and positioning the terminal 64 above the underlying substrate 50. The planar shape or section of the convex portion 61 is, for example, quadrilateral such as rectangular or square, circular, elliptical, or the like. In the convex portion 61, the end of the first lateral side 61a is angulated with respect to the adjacent upper surface of the substrate 50, and the end of the second lateral side 61b is rounded. Meanwhile, the convex portion 61 is not limited to the shown shape. A plurality of convex portions 61 is disposed on the substrate 60. The convex portions 61 are disposed as a plurality of individual islands or protrusions equal in number (for example, five) to the number of flat terminals 64.

The flexible substrate 62 includes a planar portion (first portion) 62b and a bent portion (second portion) 62d which is bent back onto a portion of planar portion 62b. The planar portion 62b of the flexible substrate 62 has a plurality of (for example, five) holes 62a for passing the convex portion 61 therethrough such that the upper portions of the convex portions 61 extend above the first portion 62b. The planar portion 62b is configured such that the convex portion 61 extends through the hole 62a, and the planar portion 62b is bonded onto the substrate 60. The bent portion 62d of the flexible substrate 62 is bent back over the planar portion 62b so as to cover the convex portion 61. The bent portion 62d of the flexible substrate 62 is bent along the shape of the convex portion 61, and is in contact with the upper surface of the convex portion 61. An end 62e of the bent portion 62d of the flexible substrate 62 is in contact with the planar portion 62b of the flexible substrate 62. An end 62c of the planar portion 62b on the bent portion 62d side is located at the end of the substrate 60, but the flexible substrate 62 may be bent back on itself before reaching the end of the substrate 60.

The internal wiring 63 is provided inside the flexible substrate 62. One end of the internal wiring 63 is connected to a corresponding signal output terminal (not shown) within the substrate 60. The other end of the internal wiring 63 is connected to the flat terminal 64. A plurality of internal wirings 63 are formed within the flexible substrate 62, and correspond to the number of flat terminals 64.

A plurality of (for example, five) flat terminals 64 are provided in the bent portion 62d of the flexible substrate 62. The flat terminal 64 is formed of, for example, a metal. The flat terminal 64 is exposed, i.e., is not covered by, the insulating outer coating of the flexible substrate 62, and is connectable to a connector (not shown) which is inserted from the A side of the module. The flat terminal 64 is bent along the surface to mimic the surface profile of the convex portion 61.

A plurality of (for example, four) flat terminals 65 are disposed (exposed at) extend through the surface of the flexible substrate 62, and are formed of, for example, a metal. Each of the flat terminals 65 is connected to a corresponding signal output terminal (not shown) within the substrate 60.

Slits 66 extend through the flexible substrate 62 and are provided on both sides, in the Y direction, and extending in an X direction, on either side of each flat terminal 64. The length of the slit 66 in an X direction is larger than, for example, the length of the flat terminal 64 in an extending direction, but there is no specific limitation thereon related to the length of the flat terminal 64.

The fixing component 67 is a component that presses down on or pinches the bent flexible substrate 62, and includes a main body 67a and a comb-shaped portion 67b of tine shaped portions extending therefrom. The comb-shaped portion 67b (a structure in the shape of a plurality of tines of a comb) protrudes from the main body 67a in a comb shape. The comb-shaped portion 67b, i.e., the tines, extend between the adjacent convex portions 61, and presses down the bent portion 62d of the flexible substrate 62, located between the slits 66 of the adjacent flat terminals 64, against the substrate 60. The comb-shaped portions 67b (tines) extends to the vicinity of the end of the slit 66 on the end 62e side of the bent portion 62d, but there is no limitation thereto based upon the length of the slits 66. The fixing component 67 includes a concave portion 67c or recess under the root of the comb-shaped portion 67b. The concave portion 67c is provided as a physical relief or space portion in order to prevent the bent portion of the flexible substrate 62 from being damaged. The base of the concave portion 67c and the flexible substrate 62 may have a gap therebetween without being in contact with one another, or may be in contact with one another over all or part of their adjacent surfaces.

As described above, in the fourth embodiment, the flexible substrate 62 having the flat terminal 64 is bent back upon itself and the flat terminal 64 is disposed over the convex portion 61. Thereby, a module having a three-dimensional flat terminal 64 is formed.

Meanwhile, the bending as used herein also includes bending in a gentle round shape without being limited to bending directly back on itself.

### [4-2] Manufacturing Method

A method of manufacturing a three dimensional terminal according to the fourth embodiment will be described with reference to FIGS. 28 to 36. Here, an example is given in which the substrate 60 and the convex portion 61 are formed integrally with each other.

As shown in FIGS. 31 and 32, the substrate 60 and the convex portion 61 are simultaneously formed by molding a single body using a sealing resin or the like. Next, the convex portions 61 are inserted through the holes 62a of the flexible substrate 62, and a portion (planar portion 62b) of the flexible substrate 62 is bonded to the substrate 60. The flat terminal 65 is exposed on a first surface of the flexible substrate 62, and the flat terminal 64 is exposed on, i.e., uncovered by, a second surface (surface on the opposite side to the first surface) of the flexible substrate 62.

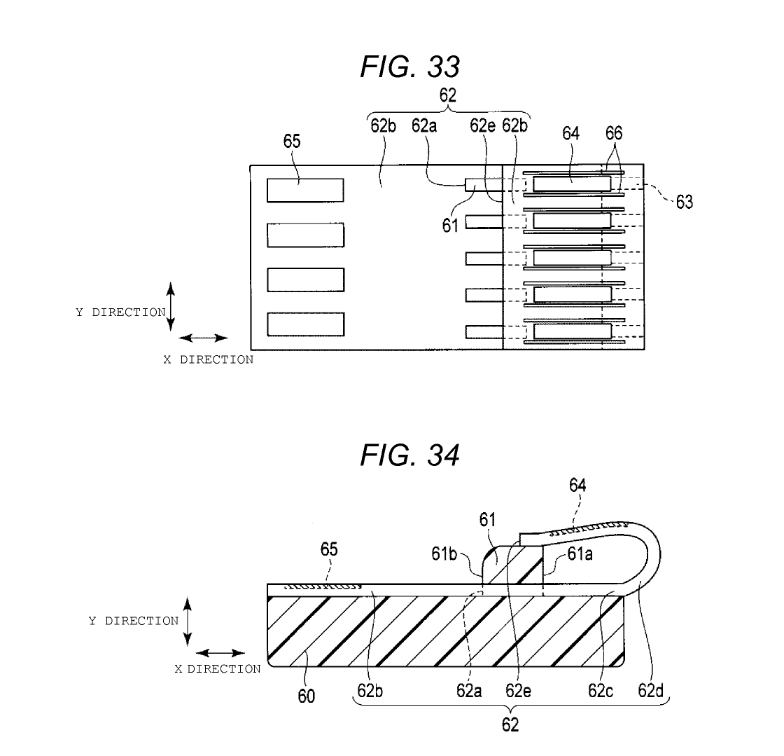

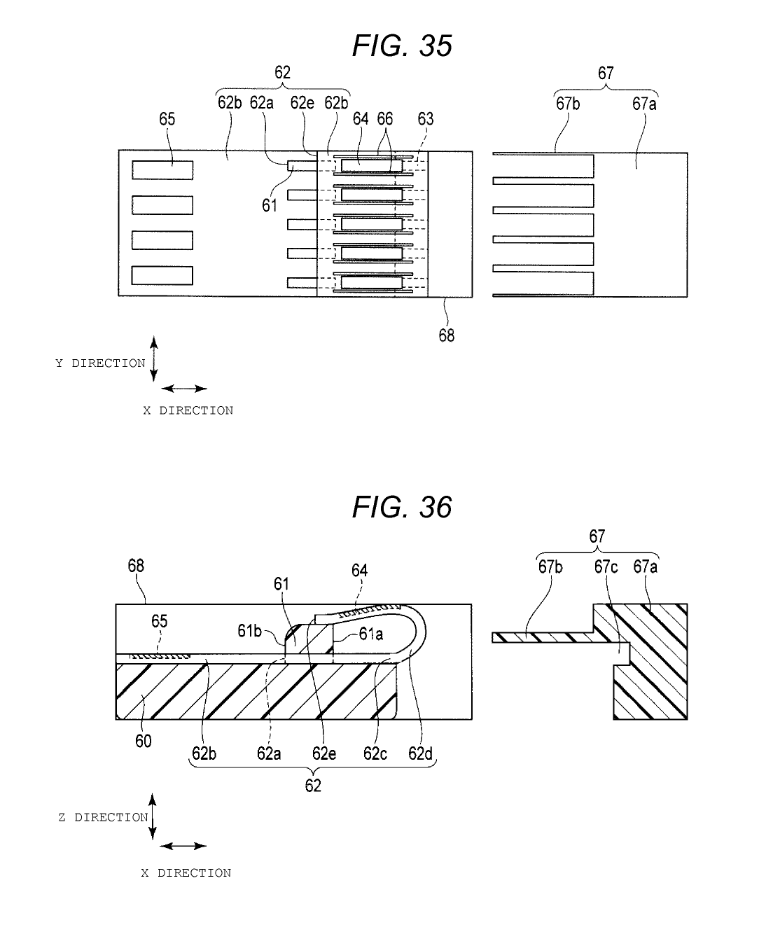

Next, as shown in FIGS. 33 and 34, the bent portion 62d of the flexible substrate 62 is bent back from the end 62c of the planar portion 62b of the flexible substrate 62 to the planar portion 62b side. As shown in FIGS. 35 and 36, the end 62e of the bent portion 62d of the flexible substrate 62 is stored in the housing 68 in a state where the end 62e is located over the upper surface of the convex portion 61. In this case, the bent portion 62d of the flexible substrate 62 is pressed down by the housing 68, and thus a state where the flexible substrate 62 is bent is maintained.

Next, as shown in FIGS. 28 to 30, the fixing component 67 is inserted into the housing 68 from the bent side direction of the flexible substrate 62. Thereby, the bent portion 62d between the slits 66 in which the flat terminal 64 is not disposed is pressed down against the substrate 60 by the comb-shaped portion 67b of the fixing component 67. As a result, the flat terminal 64 of the flexible substrate 62 is deformed to conform to the shape of the upper surface of the convex portion 61, and a module having a three dimensional terminal which is configured having the projecting flat terminal 64 is formed.

### [4-3] Effect of Fourth Embodiment

In the molded-type module according to the fourth embodiment, the three dimensional terminal is formed by bending the flexible substrate 62 having the flat terminal 64 for signal output.

Specifically, the end of the flexible substrate 62 extends from the molded substrate 60, and the flexible substrate 62 is bent back so as to cover the convex portions 61 which are provided on the substrate 60. The non-terminal portions of the flexible substrate 62 are pressed by the comb-shaped fixing component 67. Thereby, the flat terminal 64 which is provided in the flexible substrate 62 rises up from the convex portion 61, and a male (outwardly extending) three dimensional terminal is thus formed.

As described above, in the present embodiment, the flexible substrate 62 having the flat terminal 64 is bent back on itself, thereby allowing the three-dimensional flat terminal 64 to be formed without adding a complicated component. In addition, the slits 66 are provided between the flat terminal 64 and the non-terminal portions of the flexible substrate 62, thereby allowing separation and insulation between the flat terminals 64 adjacent to each other to be improved. In this manner, in the present embodiment, it is possible to achieve an improvement in the performance of the module.

### [5] Fifth Embodiment

In the fourth embodiment, the three dimensional terminal is formed by the flat terminal 64 covering the convex portion 61. On the other hand, in a fifth embodiment, the three-dimensional flat terminal 64 is formed by positioning the end 62e of the flexible substrate 62 against the side of the convex portion 61 such that the portion thereof having the flat terminal 64 therein is bowed outwardly from the body of the substrate 50. Hereinafter, an example is given in which a module according to the fifth embodiment is applied to a female connector of USB3.0, and points which are different from those in the fourth embodiment will be described.

### [5-1] Structure

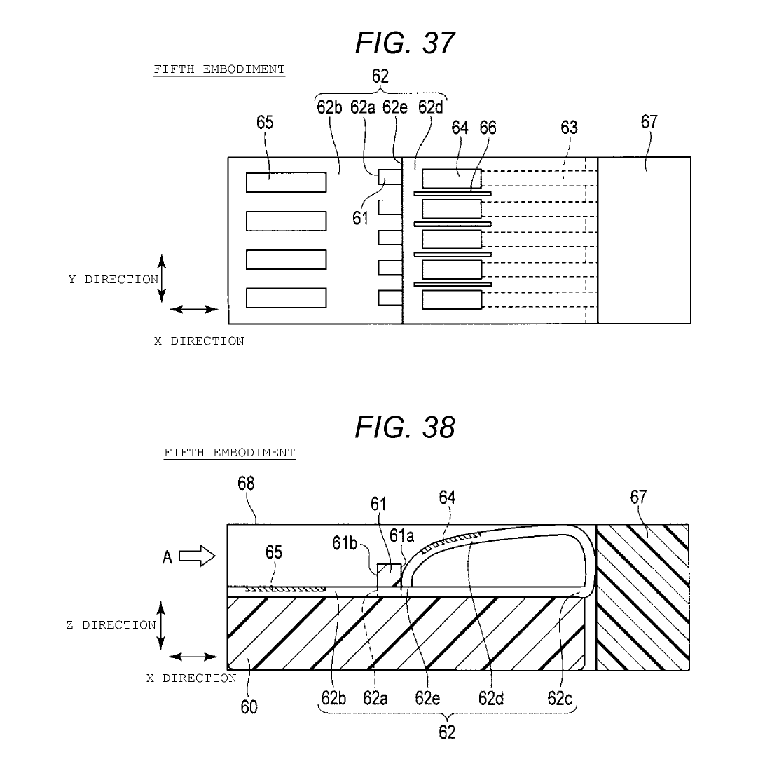

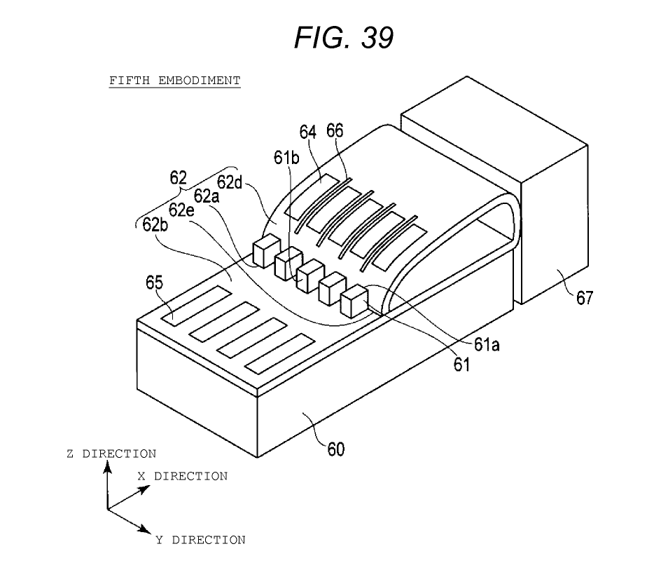

The structure of the module according to the fifth embodiment will be described with reference to FIGS. 37 to 39. Meanwhile, in FIG. 39, the housing 68 shown in FIGS. 37 and 38 is not shown.

As shown in FIGS. 37 to 39, in the module of the fifth embodiment, the bent portion 62d of the flexible substrate 62 is bent back toward the planar portion 62b, and the end 62e of the bent portion 62d is fixed at the first lateral side 61a of the convex portion 61. Thereby, the bent portion 62d of the flexible substrate 62 extends upwardly, and the flat terminal 64 is also bent along the bend of the bent portion 62d. The surface of the flat terminal 64 is thus angulated (inclined) with respect to the surface of the substrate 60, and is connected to a connector (not shown) which is inserted from the A side of the module.

The convex portion 61 is disposed at such a position that the bent portion 62d of the flexible substrate 62 extends in an upwardly bent or bowed manner. Alternatively, the convex portion 61 may be formed in one line shape extending in a Y direction (for example, direction perpendicular to the extending direction of the flexible substrate 62). The flexible substrate 62 may be provided with a concave dent instead of the convex portion 61.

The slits 66 are provided between the flat terminals 64. The length of the slit 66 in an X direction is larger than, for example, the length of the flat terminal 64 in an extending direction, but there is no limitation thereto.

The fixing component 67 is a component that compresses the bent flexible substrate 62. The upper surface of the flexible substrate 62 which is compressed by the fixing component 67 comes into contact with the housing 68. The end 62e of the bent portion 62d of the flexible substrate 62 has the state of contact between the convex portion 61 and the flexible substrate 62, the state being changed by the compression amount of the fixing component 67. For example, when the compression amount is large, the end 62e of the flexible substrate 62 comes into surface contact with the planar portion 62b. When the compression amount is small, the end 62e of the flexible substrate 62 comes into angular contact with the first lateral side 61a of the convex portion 61 and the planar portion 62b of the flexible substrate 62.

As described above, the end 62e is positionally fixed at the convex portion 61 by bending the flexible substrate 62 having the flat terminal 64. Thereby, a module having the three-dimensional flat terminal 64 is formed.

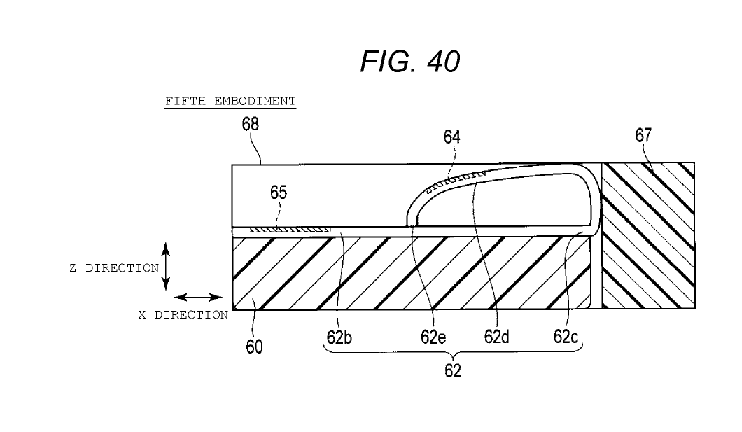

Meanwhile, as shown in FIG. 40, the end 62e may be bonded to the planar portion 62b in a state where the flexible substrate 62 is bent back into a bow, without providing the convex portion 61 on the substrate 60.

### [5-2] Manufacturing Method

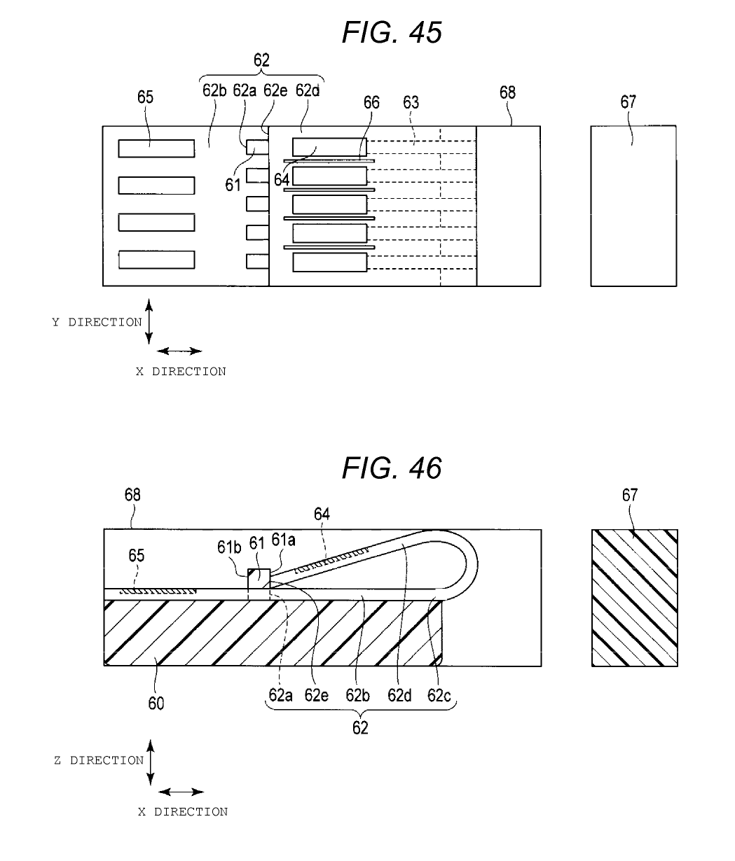

A method of manufacturing a three dimensional terminal according to the fifth embodiment will be described with reference to FIGS. 37 to 39 and FIGS. 41 to 46.

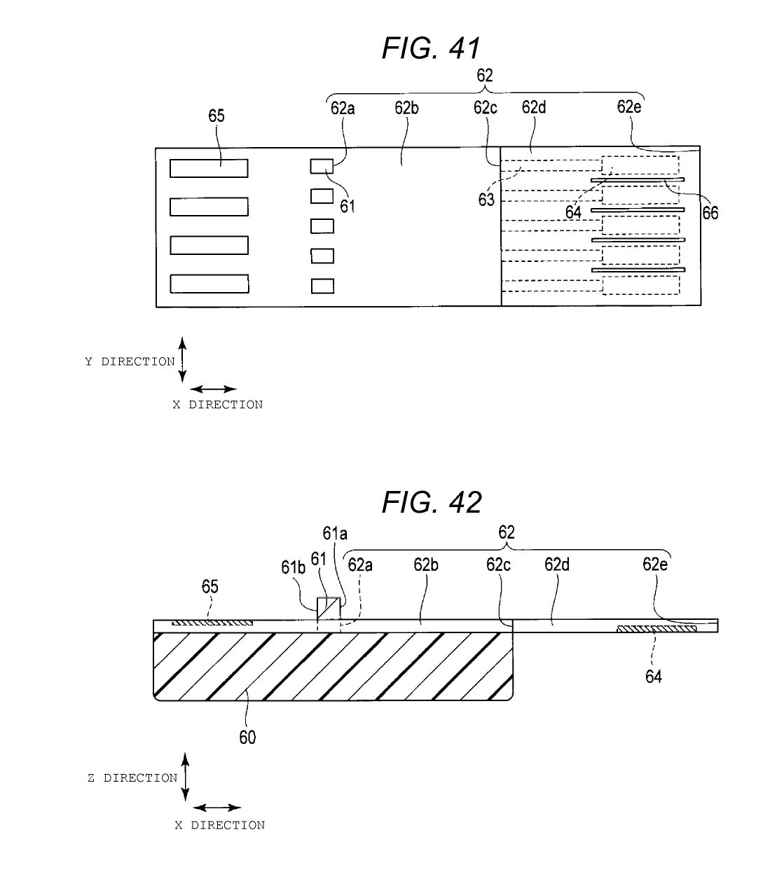

As shown in FIGS. 41 and 42, the substrate 60, the convex portion 61, and the flexible substrate 62 are formed by the same method as that in the fourth embodiment.

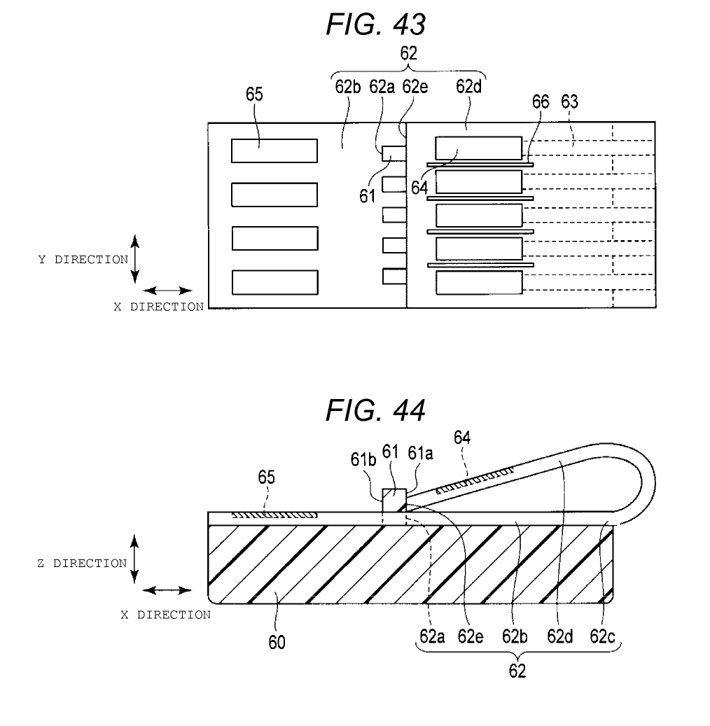

Next, as shown in FIGS. 43 and 44, the bent portion 62d of the flexible substrate 62 is bent back from the end 62c of the planar portion 62b of the flexible substrate 62. As shown in FIGS. 43 and 44, the end 62e of the flexible substrate 62 is stored in the housing 68 in a state where the end 62e comes into contact with the first lateral side 61a of the convex portion 61 and the remainder of the bent back portion extends away from the underlying substrate 50.

Next, as shown in FIGS. 37 to 39, the fixing component 67 is inserted into the housing 68 from a direction at which the flexible substrate 62 is bent. Thereby, the end 62e of the flexible substrate 62 is pressed against the first lateral side 61a of the convex portion 61 by the fixing component 67. As a result, the flat terminal 64 which is provided in the flexible substrate 62 is deformed in accordance with the compression of the fixing component 67, and a module having a three dimensional terminal is formed.

### [5-3] Effect of Fifth Embodiment

According to the above-mentioned fifth embodiment, similarly to the fourth embodiment, it is possible to form a three dimensional terminal in which the flexible substrate 62 is used.

Specifically, the flexible substrate 62 is extracted from the molded substrate 60, and is bent so that the end portion 62e of the flexible substrate 62 is positioned against the convex portion 61 which is provided on the substrate 60. The bent portion 62d of the flexible substrate is compressed, i.e., pushed against, the convex portion 61 by the fixing component 67 biasing against the end of the bent portion of the flexible substrate 60. Thereby, a structure is formed in which the surface of the flat terminal 64 has an angle with respect to the surface of the substrate 60, and a female three dimensional terminal, i.e., one which receives a terminal extending thereinto, is formed.

As described above, in the present embodiment, the flexible substrate 62 having the flat terminal 64 is bent back on itself. Thereby, it is possible to form the three-dimensional flat terminal 64 without adding a complicated component. In addition, the slits 66 are provided between the flat terminals 64 in the flexible substrate 62, thereby allowing separation and insulation between the flat terminals 64 adjacent to each other to be improved. Further, when the connector (not shown) which is inserted from the A side is connected to the flat terminal 64, it is possible to absorb stress applied to each flat terminal 64 through the slits 66, and to achieve a stable connection. In this manner, in the present embodiment, it is possible to achieve an improvement in the performance of the module.

Meanwhile, in each of the above-mentioned embodiments,

(1) In a reading operation, a voltage which is applied to a word line selected in the reading operation of an A level is, in the range of, for example, 0 V to 0.55. The voltage may be in any range of 0.1 V to 0.24 V, 0.21 V to 0.31 V, 0.31 V to 0.4 V, 0.4 V to 0.5 V, and 0.5 V to 0.55 V, without being limited thereto.

A voltage which is applied to a word line selected in the reading operation of a B level is in the range of, for example, 1.5 V to 2.3 V. The voltage may be in any range of 1.65 V to 1.8 V, 1.8 V to 1.95 V, 1.95 V to 2.1 V, and 2.1 V to 2.3 V, without being limited thereto.

A voltage which is applied to a word line selected in the reading operation of a C level is in the range of, for example, 3.0 V to 4.0 V. The voltage may be in any range of 3.0 V to 3.2 V, 3.2 V to 3.4 V, 3.4 V to 3.5 V, 3.5 V to 3.6 V, and 3.6 V to 4.0 V, without being limited thereto.

A time (tR) of the reading operation may be in any range of, for example, 25 μs to 38 μs, 38 μs to 70 μs, and 70 μs to 80 μs.

(2) The writing operation includes a program operation and a verifying operation as described above. In the writing operation, a voltage which is initially applied to a word line selected during the program operation is in the range of, for example, 13.7 V to 14.3 V. The voltage may be in any range of, for example, 13.7 V to 14.0 V and 14.0 V to 14.6 V, without being limited thereto.

A voltage which is initially applied to the selected word line during writing of odd-numbered word lines and a voltage which is initially applied to the selected word line during writing of even-numbered word lines may be changed.

When the program operation is set to an ISPP (Incremental Step Pulse Program) system, a step-up voltage includes, for example, approximately 0.5 V.

A voltage which is applied to a non-selection word line may be in the range of, for example, 6.0 V to 7.3V. The voltage may be in the range of, for example, 7.3 V to 8.4 V and may be equal to or lower than 6.0 V, without being limited to this case.

A pass voltage to be applied may be changed depending on whether the non-selection word line is an odd-numbered word line or an even-numbered word line.

A time (tProg) of the writing operation may be in the range of, for example, 1,700 μs to 1,800 μs, 1,800 μs to 1,900 μs, and 1,900 μs to 2,000 μs.

(3) In the erase operation, a voltage which is initially applied to a well, disposed on the semiconductor substrate, which has a memory cell disposed thereon is in the range of, for example, 12 V to 13.6 V. The voltage may be in any range of, for example, 13.6 V to 14.8 V, 14.8 V to 19.0 V, 19.0 V to 19.8 V, and 19.8 V to 21 V, without being limited to this case.

The time (tErase) of the erase operation may be in the range of, for example, 3,000 μs to 4,000 μs, 4,000 μs to 5,000 μs, and 4,000 μs to 9,000 μs.

(4) The structure of the memory cell includes a charge storage layer which is disposed on a semiconductor substrate (silicon substrate) through a tunnel insulating film having a thickness of 4 to 10 nm. This charge storage film may be formed to have a laminated structure of an insulating film such as a SiN film or a SiON film having a thickness of 2 nm to 3 nm, and a polysilicon film having a thickness of 3 nm to 8 nm. A metal such as Ru may be added to the polysilicon film. An insulating film is included on the charge storage film. The insulating film includes a silicon oxide film having a thickness of 4 nm to 10 nm which is interposed between a lower-layer High-k film having, for example, a thickness of 3 nm to 10 nm and an upper-layer High-k film having a thickness of 3 nm to 10 nm. Materials of the High-k film include HfO and the like. In addition, the thickness of the silicon oxide film may be made to be larger than the thickness of the High-k film. A control electrode having a thickness of 30 nm to 70 nm is formed on the insulating film through a work function adjusting film having a thickness of 3 nm to 10 nm. Here, the work function adjusting film is, for example, a metal oxide film such as TaO, or a metal nitride film such as TaN. Tungsten (W) or the like may be used in the control electrode.

In addition, an air gap may be formed between the memory cells.

The above-mentioned embodiments include the following contents.

<1> A semiconductor memory device including:
a non-volatile semiconductor memory;
a controller that controls the non-volatile semiconductor memory; and
a temperature sensor including an output terminal which is connected to a ready/busy terminal of the non-volatile semiconductor memory and a ready/busy terminal of the controller,
wherein when a temperature of the non-volatile semiconductor memory is set to be equal to or higher than a reference value, the controller stops transmitting a command to the non-volatile semiconductor memory.

<2> The semiconductor memory device according to the above <1>, wherein when the temperature of the non-volatile semiconductor memory is set to be equal to or lower than the reference value, the controller restarts transmitting a command to the non-volatile semiconductor memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A module comprising:
a substrate;
a flexible substrate including a first portion that is disposed on the substrate and a second portion that is bent from an end of the first portion back against the first portion; and
a terminal disposed in and exposed in the second portion of the flexible substrate.

2. The module according to claim 1, further comprising:
a convex portion that is disposed on the substrate,
wherein the second portion of the flexible substrate extends along the surface of the convex portion.

3. The module according to claim 1, further comprising:
a convex portion extending from the substrate,
wherein an end of the second portion of the flexible substrate is fixed to the convex portion.

4. The module according to claim 3, wherein
a surface of the terminal is inclined with respect to a surface of the substrate.

5. The module according to claim 1, wherein
the flexible substrate has a slit therethrough adjacent to the side of the terminal in an extending direction of the flexible substrate.

6. A connection terminal, comprising:
a body having at least one protrusion extending therefrom;
a flexible substrate, having a terminal associated therewith in a first portion thereof and at least one opening therethrough in a second portion thereof, the flexible substrate extending along the surface of the body wherein the at least one protrusion extends through the at least one opening;
the first portion extending over the second portion such that the terminal faces away from the second portion.

7. The connection terminal of claim 6, wherein the first portion extends across and conforms to the profile of a least a portion of the protrusion.

8. The connection terminal of claim 7, wherein the terminal extends across and conforms to the profile of a least a portion of the protrusion.

9. The connection terminal of claim 7, further comprising a fixing component extending over the first portion adjacent to the terminal thereof.

10. The connection terminal of claim 9, wherein the first portion is pressed flat against the second portion.

11. The connection terminal of claim 6, wherein the end of the first portion is disposed against the side of the protrusion, and the terminal is spaced away from the body.

12. The connection terminal of claim 11, wherein the terminal extends along a curved path spaced from the body.

13. A module comprising:
a substrate;
a convex portion disposed on the substrate;
a terminal disposed on the substrate; and
a first conductive member including a first portion which is disposed on the substrate and the terminal and is connected to the terminal, and a second portion extending from the first portion and along the surface of the convex portion.

14. The module according to claim 13, further comprising a second conductive member which is disposed on the first conductive member,
wherein one of the first conductive member and the second conductive member is a metal plate.

15. The module according to claim 14, wherein the other of the first and second conductive members is a conductive paste or a metal foil.

16. The module according to claim 13, wherein the second portion of the first conductive member has a concave surface conforming to the surface of the convex portion.

17. The module according to claim 13, wherein only a portion of the second portion of the first conductive member conforms to the surface of the convex portion.

18. The module according to claim 13, wherein the second portion further comprises a first sub portion extending along the protrusion, and a second sub portion extending away from the protrusion.

19. The module according to claim 13, wherein the second portion further comprises a third sub portion extending from the second sub portion and over the protrusion.

20. The module according to claim 13, wherein the first conductive portion extends between the second conductive portion and the protrusion.
